(19) United States
(12) Patent Application Publication
(10) Pub. No.: US 2026/0007080 A1
(43) Pub. Date: Jan. 1, 2026

(54) PHASE CHANGE MATERIAL RADIO-FREQUENCY (RF) SWITCH HAVING A REDUCED DIELECTRIC CONSTANT AROUND A HEATER ELEMENT AND METHOD FOR FORMING THE SAME

(71) Applicant: Taiwan Semiconductor Manufacturing Company Limited, Hsinchu (TW)

(72) Inventors: Tsung-Hsueh Yang, Taichung City (TW); Yu-Wen Wang, Taichung City (TW); Yu-Jui Tseng, Tainan City (TW); Fu-Ting Sung, Yangmei City (TW); Kuo-Chyuan Tzeng, Chu-Pei City (TW)

(21) Appl. No.: 18/760,400

(22) Filed: Jul. 1, 2024

(51) Int. Cl. H10N 70/00; H10N 70/20

(52) U.S. Cl. CPC H10N 70/063; H10N 70/023; H10N 70/231; H10N 70/8413; H10N 70/861

(57) ABSTRACT

A phase change memory switch may be provided by forming a heater element, a first electrode, and a second electrode over an insulating layer that overlies a substrate; by forming encapsulated cavities formed within a dielectric material layer between a strip portion of the heater element and the first electrode and between the strip portion and the second electrode by depositing a dielectric material around, and over, the heater element, the first electrode, and the second electrode; and by forming a phase change material (PCM) portion over the heater element, the first electrode, and the second electrode such that the phase change material portion contacts the first electrode and the second electrode and is spaced from the heater element.

### BACKGROUND

Phase change memory switches are useful devices that may mitigate interferences from external electromagnetic radiation, and may be used for various applications such as radio-frequency applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of an embodiment structure after formation of complementary metal-oxide-semiconductor (CMOS) transistors, metal interconnect structures and dielectric material layers, an optional dielectric capping layer, and an insulating layer according to an embodiment of the present disclosure.

FIG. 1B is a top-down view of the embodiment structure of FIG. 1A. The vertical plane A-A′ is the cut plane of the vertical cross-sectional view of FIG. 1A.

FIG. 2 is a vertical cross-sectional view of the embodiment structure after formation of an electrode material layer according to an embodiment of the present disclosure.

FIG. 3A is a vertical cross-sectional view of the embodiment structure after patterning the electrode material layer into a first electrode, a second electrode, a heater element, and metal pads according to an embodiment of the present disclosure.

FIG. 3B is a top-down view of the embodiment structure of FIG. 3A. The vertical plane A-A′ is the cut plane of the vertical cross-sectional view of FIG. 3A.

FIG. 4 is a vertical cross-sectional view of the embodiment structure after formation of a dielectric material layer including encapsulated cavities according to an embodiment of the present disclosure.

FIG. 5A is a vertical cross-sectional view of the embodiment structure after planarizing the dielectric material layer according to an embodiment of the present disclosure.

FIG. 5B is a top-down view of the embodiment structure of FIG. 5A. The vertical plane A-A′ is the cut plane of the vertical cross-sectional view of FIG. 5A.

FIG. 6A is a vertical cross-sectional view of the embodiment structure after formation of a dielectric capping layer according to an embodiment of the present disclosure.

FIG. 6B is a top-down view of the embodiment structure of FIG. 6A. The vertical plane A-A′ is the cut plane of the vertical cross-sectional view of FIG. 6A.

FIG. 7 is a vertical cross-sectional view of the embodiment structure after formation of a phase change material layer, a first cover dielectric layer, and a second cover dielectric layer according to an embodiment of the present disclosure.

FIG. 8A is a vertical cross-sectional view of the embodiment structure after patterning the second cover dielectric layer, the first cover dielectric layer, and the phase change material layer into a second cover dielectric plate, a first cover dielectric plate, and a phase change material portion according to an embodiment of the present disclosure.

FIG. 8B is a top-down view of the embodiment structure of FIG. 8A. The vertical plane A-A′ is the cut plane of the vertical cross-sectional view of FIG. 8A.

FIG. 9A is a vertical cross-sectional view of the embodiment structure after formation of a diffusion-barrier dielectric spacer according to an embodiment of the present disclosure.

FIG. 9B is a top-down view of the embodiment structure of FIG. 9A. The vertical plane A-A′ is the cut plane of the vertical cross-sectional view of FIG. 9A.

FIG. 10A is a vertical cross-sectional view of the embodiment structure after formation of a via-level dielectric layer and contact via structures according to an embodiment of the present disclosure.

FIG. 10B is a top-down view of the embodiment structure of FIG. 10A. The vertical plane A-A′ is the cut plane of the vertical cross-sectional view of FIG. 10A.

FIG. 11A is a vertical cross-sectional view of the embodiment structure after formation of a line-level dielectric layer and metal line structures according to an embodiment of the present disclosure.

FIG. 11B is a top-down view of the embodiment structure of FIG. 11A.

FIG. 12 is a first flowchart that illustrates general processing steps for manufacturing a device structure according to embodiments of the present disclosure.

FIG. 13 is a second flowchart that illustrates general processing steps for manufacturing a device structure according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are merely examples, and are not limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device structure may be rotated as needed, and the spatially relative descriptors used herein may likewise be interpreted accordingly. Elements with the same reference numerals refer to the same element, and are presumed to have the same material composition and the same thickness range unless expressly indicated otherwise.

A figure of merit for measuring an effectiveness of a phase change memory (PCM) switch is given by ½πRₒₙC_{off}, in which Rₒₙ represents the resistance of the phase change memory switch in the on state, and C_{off} represents the capacitance of the phase change memory switch in the off state. The figure of merit for PCM switches is often constrained by the off-state capacitance and the on-state resistance. Typically, an increase in a lateral distance between a heater element and electrodes of a PCM switch results in a decrease in the off-state capacitance at the cost of an increase in the on-state resistance. Conversely, a decrease in the lateral distance between the heater element and the electrodes of the PCM switch results in a decrease in the on-state resistance at the cost of an increase in the off-state capacitance. Thus, reducing one of the on-state resistance and the off-state capacitance without affecting the other remains a challenge for manufacture of PCM switches.

Embodiments of the present disclosure maintains or reduces the off-state capacitance by introducing air gaps in between the heater and the electrodes while the lateral distances between the electrodes and the heater are shortened to lower the on-state resistance. The air gap structures include encapsulated cavities formed within a dielectric material layer. In one embodiment, the encapsulated cavities provide volumes in which the dielectric constant is 1.0 without increasing the lateral distance between the electrodes. By not increasing the lateral distance between the electrodes, the on-state resistance of the PCM switch does not increase. Alternatively or additionally, the on-state resistance of the PCM switch may also be reduced while the off-state capacitance of the PCM switch is reduced, or remains the same. Thus, embodiments of the present disclosure may provide a PCM switch having a reduced off-state capacitance and/or a reduced on-state resistance, and thus, having an increased figure of merit. The manufacture methods of the present disclosure do not increase the number of processing steps and does not use an additional mask level, but provides a high performance PCM switch with a minimal increment in the manufacture cost. The various embodiments of the present disclosure are now described with reference to accompanying drawings.

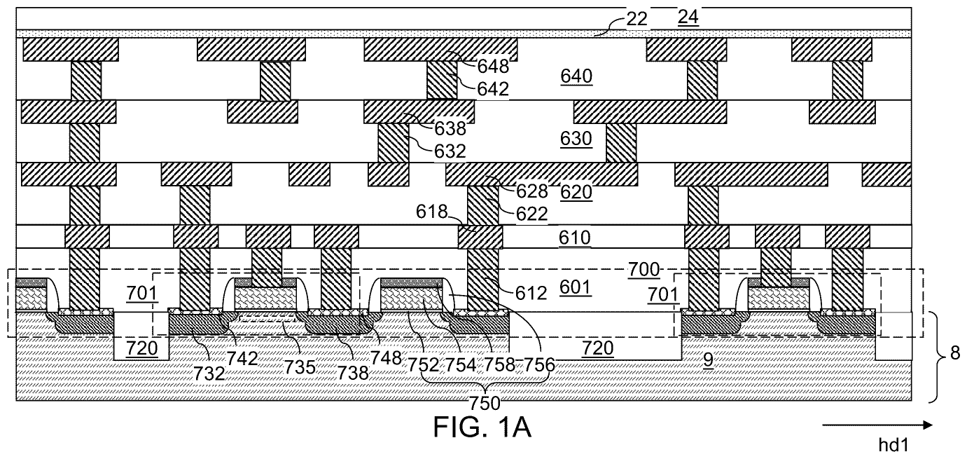

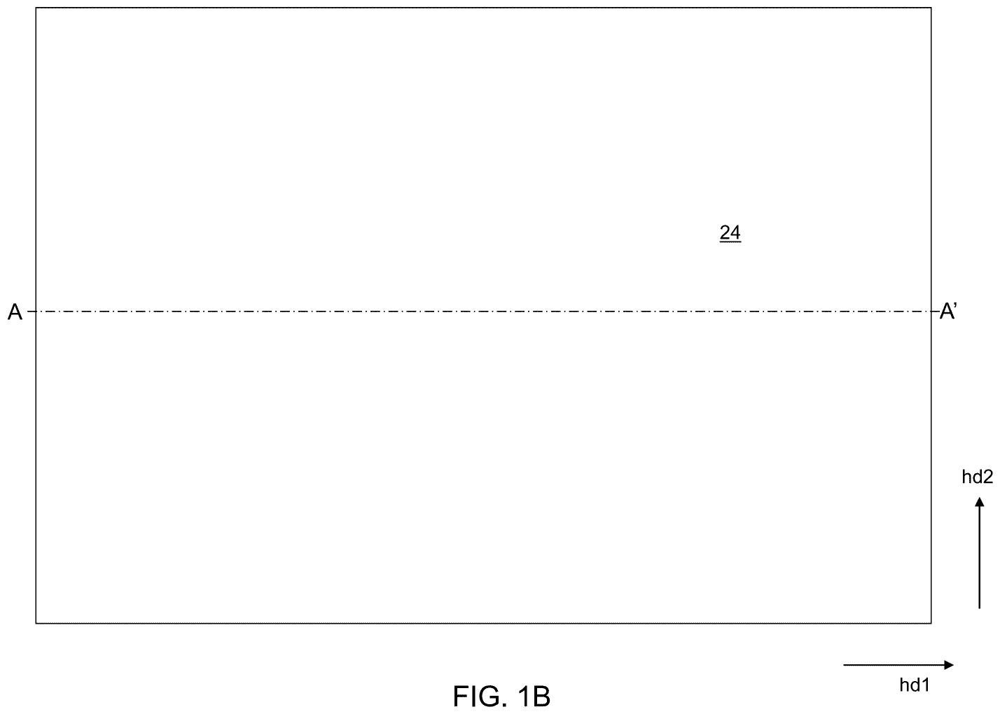

Referring to FIGS. 1A and 1B, an embodiment structure according to the present disclosure is illustrated. The embodiment structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 701 may be formed over the top surface of the semiconductor material layer 9. For example, each field effect transistor 701 may include a source contact electrode 732, a drain contact electrode 738, a semiconductor channel 735 that includes a surface portion of the substrate 8 extending between the source contact electrode 732 and the drain contact electrode 738, and a gate structure 750. The semiconductor channel 735 may include a single crystalline semiconductor material. Each gate structure 750 may include a gate dielectric layer 752, a gate contact electrode 754, a gate cap dielectric 758, and a dielectric gate spacer 756. A source-side metal-semiconductor alloy region 742 may be formed on each source contact electrode 732, and a drain-side metal-semiconductor alloy region 748 may be formed on each drain contact electrode 738. The devices formed on the top surface of the semiconductor material layer 9 may include complementary metal-oxide-semiconductor (CMOS) transistors and optionally additional semiconductor devices (such as resistors, diodes, capacitor structures, etc.), and are collectively referred to as CMOS circuitry 700.

One or more of the field effect transistors 701 in the CMOS circuitry 700 may include a semiconductor channel 735 that contains a portion of the semiconductor material layer 9 in the substrate 8. In embodiments in which the semiconductor material layer 9 includes a single crystalline semiconductor material such as single crystalline silicon, the semiconductor channel 735 of each field effect transistor 701 in the CMOS circuitry 700 may include a single crystalline semiconductor channel such as a single crystalline silicon channel. In one embodiment, a subset of the field effect transistors 701 in the CMOS circuitry 700 may include a respective node that is subsequently electrically connected to a node of an energy harvesting device and/or to a battery structure to be subsequently formed.

In one embodiment, the substrate 8 may include a single crystalline silicon substrate, and the field effect transistors 701 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

Various metal interconnect structures formed within dielectric material layers may be subsequently formed over the substrate 8 and the semiconductor devices thereupon (such as field effect transistors 701). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, a second interconnect-level dielectric material layer 620, a third interconnect-level dielectric material layer 630, and a fourth interconnect-level dielectric material layer 640. The metal interconnect structures may include device contact via structures 612 formed in the first dielectric material layer 601 and contact a respective component of the CMOS circuitry 700, first metal line structures 618 formed in the first interconnect-level dielectric material layer 610, first metal via structures 622 formed in a lower portion of the second interconnect-level dielectric material layer 620, second metal line structures 628 formed in an upper portion of the second interconnect-level dielectric material layer 620, second metal via structures 632 formed in a lower portion of the third interconnect-level dielectric material layer 630, third metal line structures 638 formed in an upper portion of the third interconnect-level dielectric material layer 630, third metal via structures 642 formed in a lower portion of the fourth interconnect-level dielectric material layer 640, and fourth metal line structures 648 formed in an upper portion of the fourth interconnect-level dielectric material layer 640. While the present disclosure is described using an embodiment in which four levels metal line structures are formed in dielectric material layers, embodiments are expressly contemplated herein in which a lesser or greater number of levels of metal line structures are formed in dielectric material layers.

Each of the dielectric material layers (601, 610, 620, 630, 640) may include a dielectric material such as undoped silicate glass, a doped silicate glass, organosilicate glass, amorphous fluorinated carbon, porous variants thereof, or combinations thereof. Each of the metal interconnect structures (612, 618, 622, 628, 632, 638, 642, 648) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. Generally, any contiguous set of a metal line structure (628, 638, 648) and at least one underlying metal via structure (622, 632, 642) may be formed as an integrated line and via structure.

Generally, semiconductor devices (such as field effect transistors 701) may be formed on a substrate 8, and metal interconnect structures (612, 618, 622, 628, 632, 638, 642, 648) and dielectric material layers (601, 610, 620, 630, 640) over the semiconductor devices (such as the field effect transistors 701). The metal interconnect structures (612, 618, 622, 628, 632, 638, 642, 648) may be formed in the dielectric material layers (601, 610, 620, 630, 640), and may be electrically connected to the semiconductor devices.

An optional dielectric capping layer 22 and an insulating layer 24 may be deposited over the metal interconnect structures (612, 618, 622, 628, 632, 638, 642, 648) and dielectric material layers (601, 610, 620, 630, 640). The optional dielectric capping layer 22 includes a dielectric capping material such as silicon carbide, silicon nitride, or silicon carbide nitride. Other suitable dielectric capping materials are within the contemplated scope of disclosure. The thickness of the optional dielectric capping layer 22, if present, may be in a range from 2 nm to 100 nm, although lesser and greater thicknesses may also be used. The insulating layer 24 comprises a dielectric material such as undoped silicate glass or a doped silicate glass. The insulating layer 24 may comprise a planar top surface, i.e., a top surface located entirely within a horizonal plane. The thickness of the insulating layer 24 may be in a range from 100 nm to 300 nm, such as from 120 nm to 200 nm, although lesser and greater thicknesses may also be used.

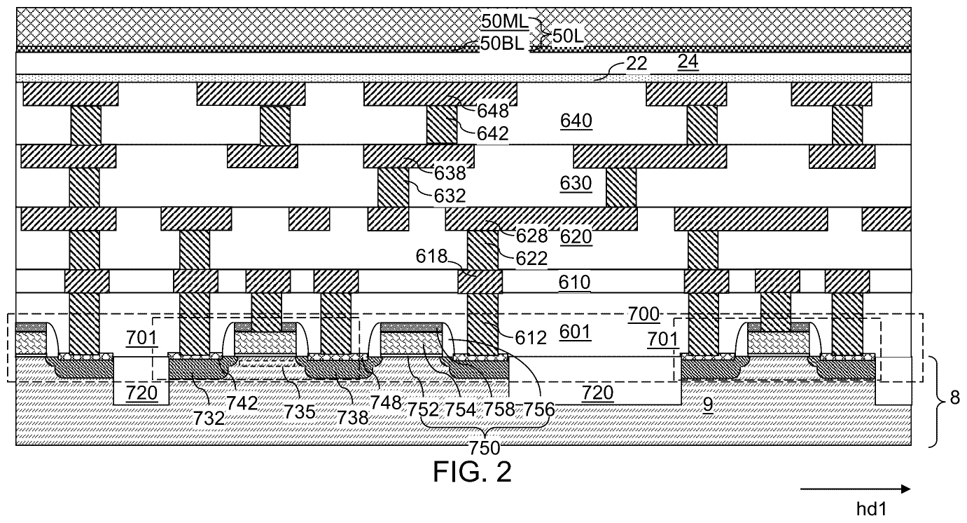

Referring to FIG. 2, an electrode material layer 50L may be deposited over the insulating layer 24. The electrode material layer 50L comprises at least one metallic material that may withstand an elevated temperature that is sufficiently high to induce melting of a phase change material. For example, the electrode material layer 50L comprises at least one material having a melting point higher than 1,500 degrees Celsius, and preferably higher than 1,750 degrees Celsius, and more preferably higher than 2,000 degrees Celsius.

In one embodiment, the electrode material layer 50L consists essentially of a set of at least one metallic material that is selected from tungsten, tantalum, molybdenum, niobium, rhenium, tungsten nitride, tantalum nitride, titanium nitride, and molybdenum nitride. In one embodiment, the electrode material layer 50L may comprise a metallic barrier material layer 50BL and/or a refractory metal layer 50ML. The metallic barrier material layer 50BL may consist essentially of a metallic nitride material that is selected from tungsten nitride, tantalum nitride, titanium nitride, and molybdenum nitride. The refractory metal layer 50ML may comprise a refractive elementary metal that is selected from tungsten, tantalum, molybdenum, niobium, and rhenium. In a non-limiting illustrative example, the electrode material layer 50L may comprise a metallic barrier material layer 50BL including titanium nitride having a melting point of 2,930 degrees Celsius, and a refractory metal layer 50ML including tungsten having a melting point of 3,422 degrees Celsius.

Generally, the electrode material layer 50L may be deposited by physical vapor deposition (PVD) and/or chemical vapor deposition (CVD). The thickness of the electrode material layer 50L may be in a range from 30 nm to 300 nm, such as from 60 nm to 150 nm, although lesser and greater thicknesses may also be used.

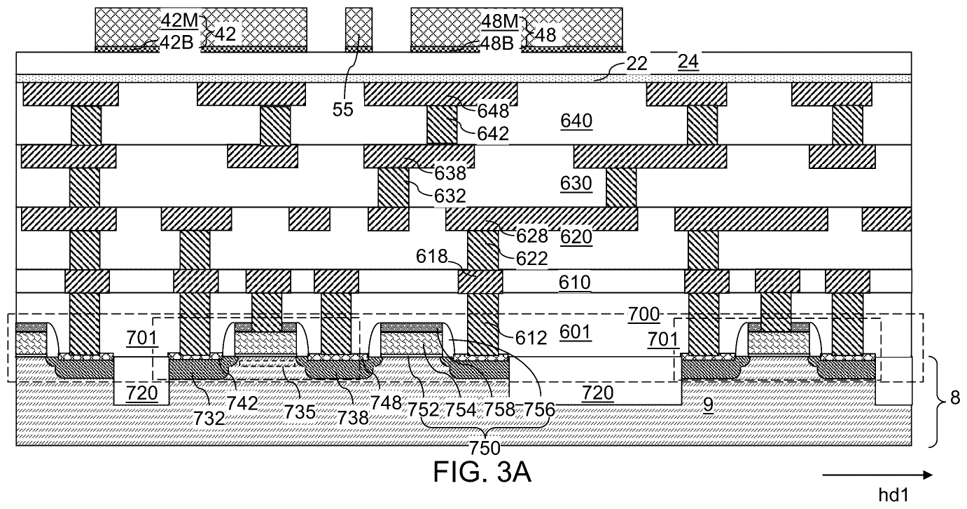

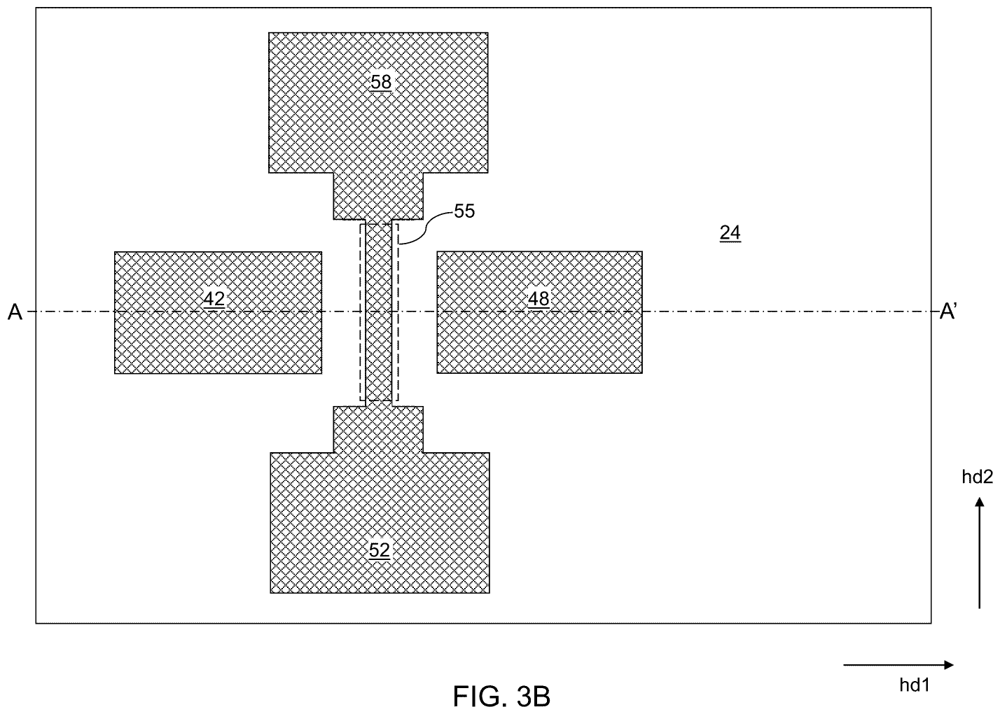

Referring to FIGS. 3A and 3B, an etch mask layer (such as a patterned photoresist layer) may be applied over the electrode material layer 50L, and may be lithographically patterned to form a patterned etch mask layer (not illustrated). An etch process (such as a reactive ion etch process) may be performed to transfer the pattern in the patterned etch mask layer through the electrode material layer 50L. The pattern in the patterned etch mask layer may be selected such that patterned remaining portions of the electrode material layer 50L comprises a heater element (52, 55, 58) of a phase change material (PCM) switch, a first electrode 42 of the PCM switch, and a second electrode 48 of the PCM switch. For example, the heater element (52, 55, 58) may comprise a first patterned portion of the electrode material layer 50L, the first electrode 42 of the PCM switch may comprise a second patterned portion of the electrode material layer 50L, and the second electrode 48 of the PCM switch may comprise a third patterned portion of the electrode material layer 50L.

Generally, the heater element (52, 55, 58) comprises a strip portion 55 having a narrow uniform width along a first horizontal direction hd1 and laterally extending along a second horizontal direction hd2 that is perpendicular to the first horizontal direction hd1; a first terminal portion 52 adjoined to a first end of the strip portion 55; and a second terminal portion 58 adjoined to a second end of the strip portion 55 and laterally spaced from the first terminal portion 52 along the second horizontal direction hd2. The uniform width of the strip portion 55 along the first horizontal direction may be a critical dimension, i.e., the smallest dimension that may be printed using a single lithographic exposure with the lithography tool used to pattern the etch mask layer (such as the patterned photoresist layer). For example, the uniform width of the strip portion 55 may be in a range from 10 nm to 60 nm, such as from 20 nm to 40 nm, although lesser and greater dimensions may also be used. The ratio of the length of the strip portion 55 to the width of the strip portion 55 may be in a range from 3 to 60, such as from 6 to 30, although lesser and greater ratios may also be used.

Each of the first terminal portion 52 and the second terminal portion 58 may comprise a respective pad region, which may have a shape of a respective rectangle or a rounded rectangle. Each pad region may be adjoined to the strip portion 55 by an respective intermediate region having a lesser width along the first horizontal direction than the pad region. Each intermediate region may have a shape of a respective rectangle or a respective trapezoid. The first terminal portion 52 is adjoined to a first end of the strip portion 55, and the second terminal portion 58 is adjoined to a second end of the strip portion 55.

The entirety of the heater element (52, 55, 58) of the phase change memory (PCM) switch may be formed over the top surface of the insulating layer 24. The entirety of the first electrode 42 of the phase change memory (PCM) switch may be formed over the top surface of the insulating layer 24. The entirety of the second electrode 48 of the phase change memory (PCM) switch may be formed over the top surface of the insulating layer 24.

In one embodiment, the electrode material layer 50L may consist essentially of a set of at least one metallic material selected from tungsten, tantalum, molybdenum, niobium, rhenium, tungsten nitride, tantalum nitride, titanium nitride, and molybdenum nitride. The heater element (52, 55, 58), the first electrode 42, and the second electrode 48 may have the same material composition. The heater element (52, 55, 58) may comprise, and/or may consist of, a first portion of the set of at least one metallic material. The first electrode 42 may comprise, and/or may consist essentially of, a second portion of the set of at least one metallic material, and may be laterally spaced from the strip portion 55 of the heater element (52, 55, 58) along the first horizontal direction hd1. The second electrode 48 may comprise, and/or may consist essentially of, a third portion of the set of at least one metallic material, and may be laterally spaced from the heater element (52, 55, 58) along the first horizontal direction hd1.

In one embodiment, the heater element (52, 55, 58) comprises at least one of a heater metallic barrier material layer 55B (which is a patterned portion of the metallic barrier material layer 50BL) and a heater refractory metal layer 55M (which is a patterned portion of the refractory metal layer 50ML). In one embodiment, the heater element (52, 55, 58) may comprise a stack of a heater metallic barrier material layer 55B and a heater refractory metal layer 55M. In one embodiment, the first electrode 42 comprises at least one of a first electrode metallic barrier material layer 42B (which is a patterned portion of the metallic barrier material layer 50BL) and a first electrode refractory metal layer 42M (which is a patterned portion of the refractory metal layer 50ML). In one embodiment, the first electrode 42 may comprise a stack of a first electrode metallic barrier material layer 42B and a first electrode refractory metal layer 42M. In one embodiment, the second electrode 48 comprises at least one of a second electrode metallic barrier material layer 48B (which is a patterned portion of the metallic barrier material layer 50BL) and a second electrode refractory metal layer 48M (which is a patterned portion of the refractory metal layer 50ML). In one embodiment, the second electrode 48 may comprise a stack of a second electrode metallic barrier material layer 48B and a second electrode refractory metal layer 48M.

The strip portion 55 of the heater element (52, 55, 58) laterally extends between the first electrode 42 and the second electrode 48 along the second horizontal direction hd2. Each of the first electrode 42 and the second electrode 48 may have a respective rectangular shape. The width of each of the first electrode 42 and the second electrode 48 along the second horizontal direction hd2 may be in a range from 50% to 96%, such as from 70% to 90%, of the length of the strip portion 55 of the heater element (52, 55, 58). The length of each of the first electrode 42 and the second electrode 48 along the first horizontal direction hd1 may be in a range from 50% to 300% of the width of each of the first electrode 42 and the second electrode 48 along the second horizontal direction hd2, although lesser and greater lengths may also be used.

In one embodiment, the top surface of the heater element (52, 55, 58), the top surface of the first electrode 42, and the top surface of the second electrode 48 may be formed within a first horizontal plane. The bottom surface of the heater element (52, 55, 58), the bottom surface of the first electrode 42, and the bottom surface of the second electrode 48 may be formed within a second horizontal plane that includes the top surface of the insulating layer 24.

The first electrode 42 and the second electrode 48 are laterally spaced apart from each other along the first horizontal direction hd1. The strip portion 55 of the heater element (52, 55, 58) laterally extends between the first electrode 42 and the second electrode 48 along the second horizontal direction hd2. The width of the strip portion 55 along the first horizontal direction hd1 may be uniform throughout. In one embodiment, the width of the strip portion 55 may be in a range from 10 nm to 100 nm, such as from 20 nm to 60 nm, although lesser and greater widths may also be used. The lateral separation distance between the first electrode 42 and the second electrode 48 may be in a range from 2 times the width of the strip portion 55 to 10 times the width of the strip portion 55, such as from 3 times the width of the strip portion 55 to 5 times the width of the strip portion 55. A first gap is present between the strip portion 55 of the heater element (52, 55, 58) and the first electrode 42, and a second gap is present between the strip portion 55 of the heater element (52, 55, 58) and the second electrode 48. The first gap may have an aspect ratio greater than 1.0, and the second gap may have an aspect ratio greater than 1.0. In one embodiment, the first gap and the second gap may have aspect ratios greater than 2.0, and/or greater than 3.0, and/or greater than 5.0. As used herein, an “aspect ratio” refers to the ratio of the vertical dimension (such as a height) to the lateral dimension (such as a width).

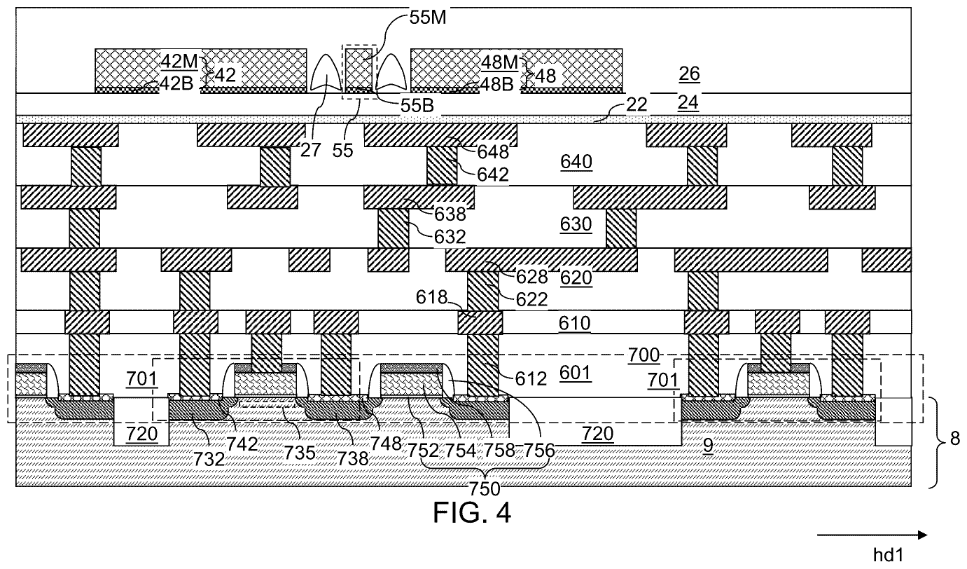

Referring to FIG. 4, a dielectric material may be deposited over the various patterned portions of the electrode material layer 50L, which includes the heater element (52, 55, 58), the first electrode 42, and the second electrode 48. The dielectric material comprises a planarizable dielectric material that may be subsequently planarized by chemical mechanical polishing. For example, the dielectric material may comprise undoped silicate glass having a dielectric constant of 3.9, a doped silicate glass having a dielectric constant in a range from 3.5 to 3.9, organosilicate glass having a dielectric constant in a range from 2.2 to 3.0, or nanoglass having a dielectric constant of about 1.3. The dielectric material may be deposited in a manner that induces formation of gaps in recessed surfaces. In a non-limiting illustrative example, a plasma-enhanced chemical vapor deposition process may be used to deposit the dielectric material.

Generally, any deposition process that forms air gaps in recessed volumes may be used. In a non-limiting illustrative example, the dielectric material may be deposited with sufficiently high directionality along a downward vertical direction such that encapsulated cavities 27 are formed in gaps having high aspect ratios. In some embodiments, an anisotropic deposition process may be effective in forming air gaps, especially in configurations having a respectively low aspect ratio (such as a configuration having a wider gap). Specifically, a first encapsulated cavity 27 is formed in the first gap between the first electrode 42 and the strip portion 55 of the heater element (52, 55, 58), and a second encapsulated cavity 27 is formed in the second gap between the second electrode 48 and the strip portion 55 of the heater element (52, 55, 58). The anisotropically deposited dielectric material forms a dielectric material layer 26 that covers the heater element (52, 55, 58), the first electrode 42, and the second electrode 48. Generally, encapsulated cavities 27 formed within the dielectric material layer 26 may be formed between the strip portion 55 and the first electrode 42 and between the strip portion 55 and the second electrode 48 by anisotropically depositing a dielectric material around, and over, the heater element (52, 55, 58), the first electrode 42, and the second electrode 48. The encapsulated cavities 27 are free of any solid phase material, and may comprise vacuum or a residual gas from the anisotropic deposition process.

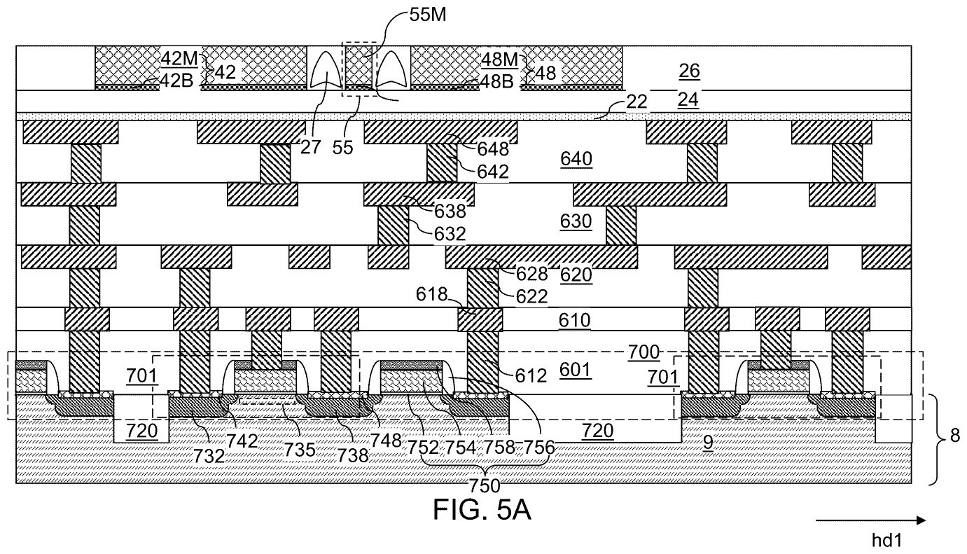

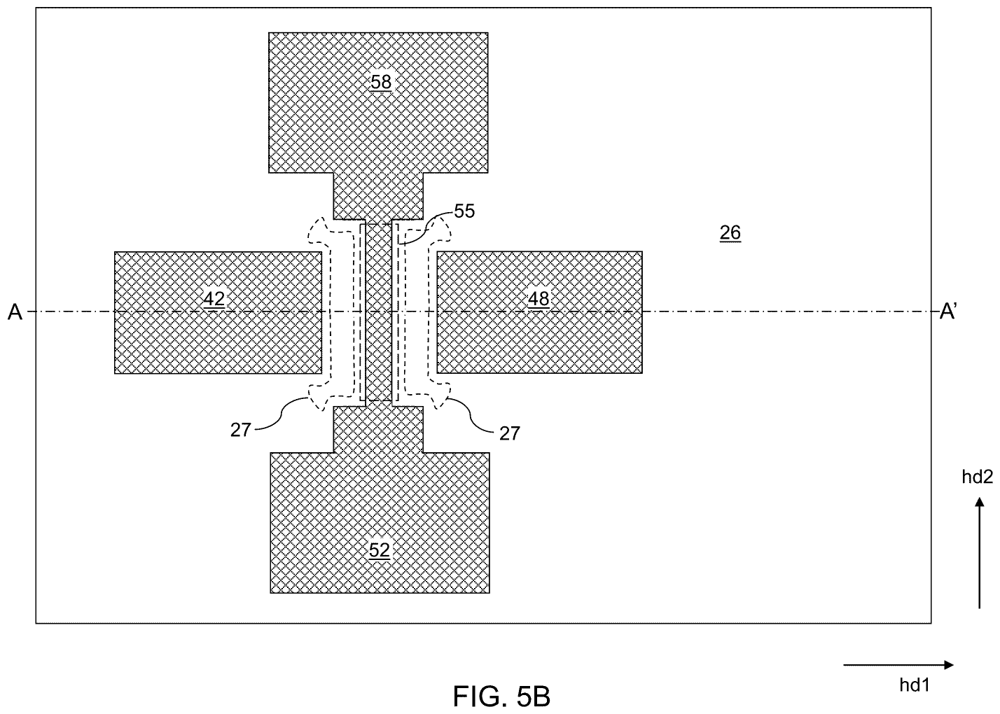

Referring to FIGS. 5A and 5B, a chemical mechanical polishing (CMP) process may be performed to remove portions of the dielectric material layer 26 that overlie the horizontal plane including the top surfaces of the heater element (52, 55, 58), the first electrode 42, and the second electrode 48. The dielectric material of the dielectric material layer 26 may be planarized using top surfaces of the heater element (52, 55, 58), the first electrode 42, and the second electrode 48 as stopping surfaces. Top surfaces of the heater element (52, 55, 58), the first electrode 42, and the second electrode 48 may be physically exposed after the planarization process. In this embodiment, the top surface of the dielectric material layer 26 may be formed within a horizontal plane including the top surfaces of the heater element (52, 55, 58), the first electrode 42, and the second electrode 48. Thus, the top surfaces of the heater element (52, 55, 58), the first electrode 42, and the second electrode 48 may be coplanar with the top surface of the remaining portion of the dielectric material layer 26.

The dielectric material layer 26 laterally surrounds the heater element (52, 55, 58), the first electrode 42, and the second electrode 48. According to an aspect of the present disclosure, the dielectric material layer 26 having formed therein a first encapsulated cavity 27 between the strip portion 55 of the heater element (52, 55, 58) and the first electrode 42, and a second encapsulated cavity 27 between the strip portion 55 and the second electrode 48. All surfaces of the encapsulated cavities 27 are surfaces of the dielectric material layer 26, and the encapsulated cavities 27 are free of any solid phase material therein.

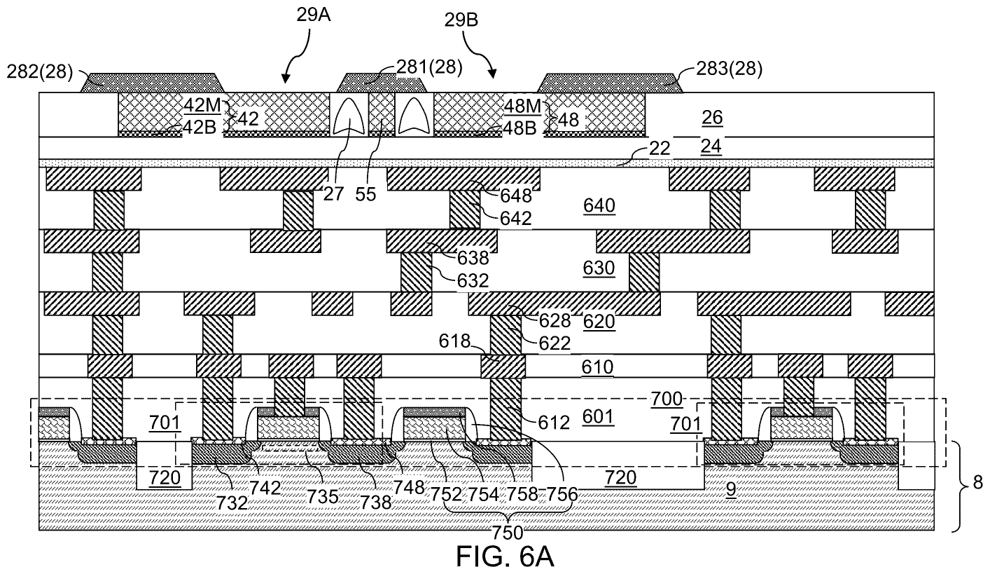

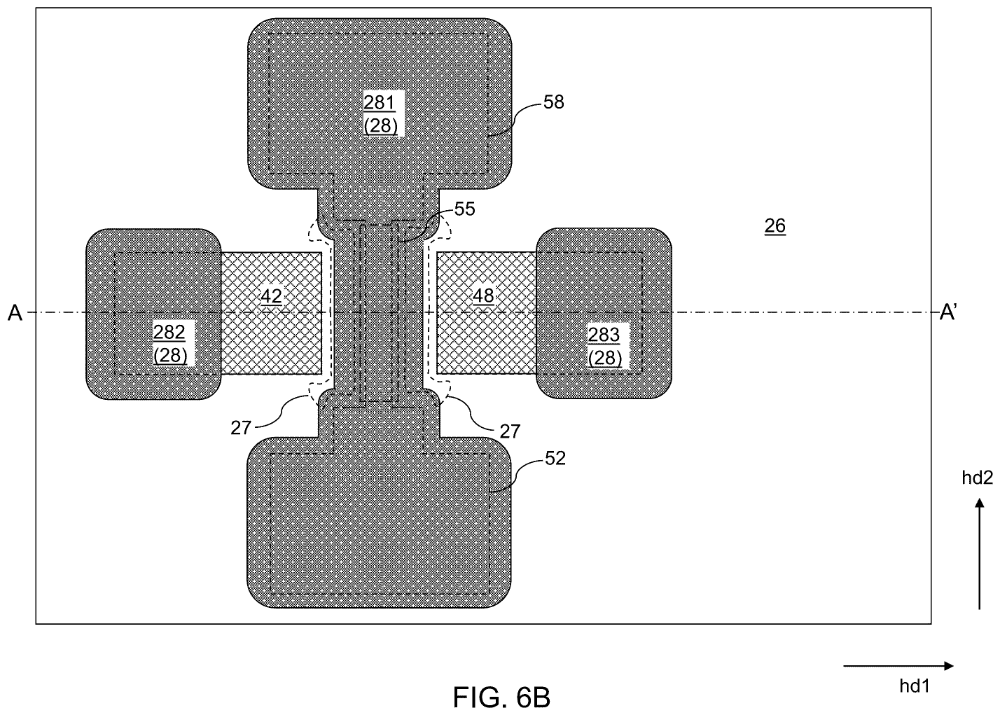

Referring to FIGS. 6A and 6B, a dielectric capping layer may be formed over the dielectric material layer 26, and may be patterned into dielectric capping plates 28. The dielectric capping layer comprises a dielectric barrier material, i.e., a dielectric material that functions as a diffusion barrier material. Preferably, the dielectric capping layer comprises a dielectric material that may provide a reasonably high thermal conductivity to facilitate heat dissipation from the heater element (52, 55, 58). For example, the dielectric capping layer may comprise silicon nitride or silicon carbonitride. The dielectric capping layer may be deposited by chemical vapor deposition, and may have a thickness in a range from 6 nm to 60 nm, such as from 12 nm to 30 nm, although lesser and greater thicknesses may also be used.

A photoresist layer (not shown) may be applied over the dielectric capping layer, and may be lithographically patterned to form discrete patterns that cover a distal portion the first electrode 42, a distal portion the second electrode 48, and the heater element (52, 55, 58). A proximal portion of the first electrode 42 that is proximal to the second electrode 48, and a proximal portion of the second electrode 48 that is proximal to the first electrode 42 are not covered by the patterned photoresist layer. An etch process may be performed to etch portions of the dielectric capping layer that are not masked by the photoresist layer. The etch process etches the material of the dielectric capping layer selective to the materials of the first electrode 42, the second electrode 48, the heater element (52, 55, 58), and the dielectric material layer 26. The etch process may comprise an anisotropic etch process (such as a reactive ion etch process) or an isotropic etch process (such as a wet etch process). The patterned portions of the dielectric capping layer comprise the dielectric capping plates 28. The photoresist layer may be subsequently removed, for example, by ashing.

The dielectric capping plates 28 may comprise a first dielectric capping plate 281 that covers the heater element (52, 55, 58), a second dielectric capping plate 282 that covers the distal portion of the first electrode 42, and a third dielectric capping plate 283 that covers the distal portion of the second electrode 48. A first gap 29A that is not covered by the dielectric capping plates 28 is present between the first dielectric capping plate 281 and the second dielectric capping plate 282, and a second gap 29B that is not covered by the dielectric capping plates 28 is present between the first dielectric capping plate 281 and the third dielectric capping plate 283.

In one embodiment, the entirety of the top surface of the strip portion 55 may be contacted by the first dielectric capping plate 281. A proximal surface segment of the top surface of the first electrode 42 is exposed underneath the first gap 29A. A proximal surface segment of the second electrode 48 is exposed underneath the second gap 29B. In one embodiment, a surface portion of the top surface of the dielectric material layer 26 overlying an encapsulated cavity 27 may, or may not, be physically exposed to the first gap 29A or to the second gap 29B. Generally, a surface portion of the first electrode 42 is exposed within an area of the first gap 29A, and a surface portion of the second electrode 48 is exposed within an area of the second gap 29B.

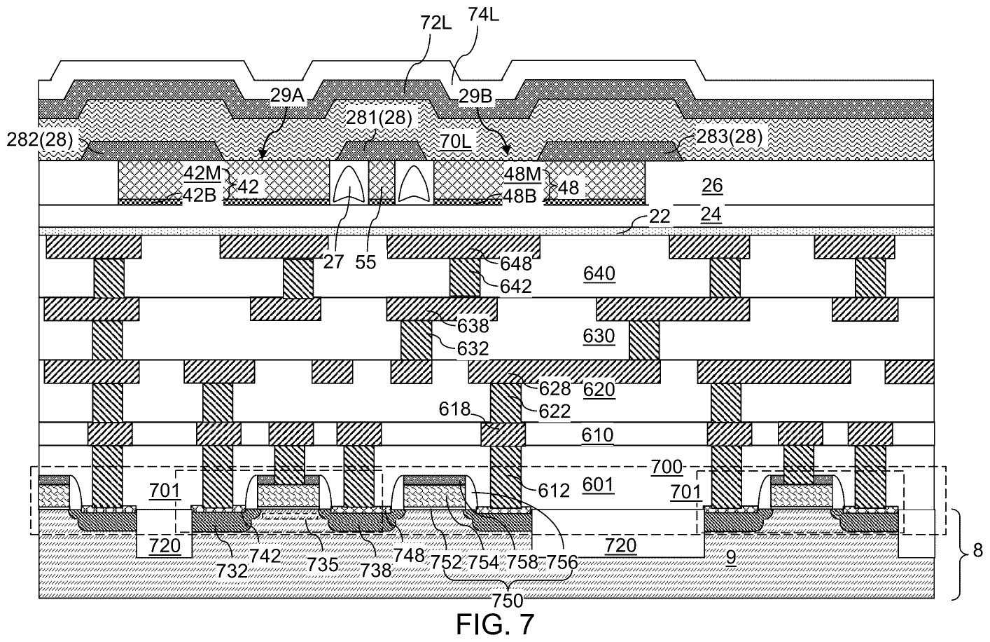

Referring to FIG. 7, a phase change material (PCM) layer 70L and at least one cover dielectric layer (72L, 74L) may be deposited over the dielectric capping plates 28 and over the heater element (52, 55, 58), the first electrode 42, and the second electrode 48. The phase change material layer 70L may be deposited directly on the physically exposed top surface portions of the first electrode 42 and the second electrode 48.

The phase change material layer 70L comprises, and/or consists essentially of, a phase change material. As used herein, a “phase change material” refers to a material having at least two different phases providing different resistivity. A phase change material (PCM) may be used to store information as a resistivity state of a material that may be in different resistivity states corresponding to different phases of the material. The different phases may include an amorphous state having high resistivity and a crystalline state having low resistivity (i.e., a lower resistivity than in the amorphous state). The transition between the amorphous state and the crystalline state may be induced by controlling the rate of cooling after application of an electrical pulse that renders the phase change material amorphous in a first part of a programming process. The second part of the programming process includes control of the cooling rate of the phase change material. In embodiments in which rapid quenching occurs, the phase change material may cool into an amorphous high resistivity state. In embodiments in which slow cooling occurs, the phase change material may cool into a crystalline low resistivity state.

Exemplary phase change materials include, but are not limited to, germanium antimony telluride (GST) compounds such as Ge₂Sb₂Te₅ or GeSb₂Te₄, germanium antimony compounds, indium germanium telluride compounds, aluminum selenium telluride compounds, indium selenium telluride compounds, and aluminum indium selenium telluride compounds. The phase change material may be doped (e.g., nitrogen doped GST) or undoped to enhance resistance-switching characteristics. The phase change material layer 70L may be deposited by physical vapor deposition. The thickness of the phase change material layer 70L may be in a range from 30 nm to 600 nm, such as from 60 nm to 300 nm, although lesser and greater thicknesses may also be used.

At least one cover dielectric layer (72L, 74L) may be deposited over the phase change material layer 70L. In one embodiment, the at least one cover dielectric layer (72L, 74L) may comprise a stack of a first cover dielectric layer 72L and a second cover dielectric layer 74L. In one embodiment, the first cover dielectric layer 72L may comprise a dielectric barrier material such as silicon nitride or silicon carbonitride, and the second cover dielectric layer 74L may comprise a dielectric material that is different from the dielectric barrier material. For example, the second cover dielectric layer 74L may comprise silicon oxide. The first cover dielectric layer 72L and the second cover dielectric layer 74L may be deposited by a respective chemical vapor deposition. The thickness of the first cover dielectric layer 72L may be in a range from 10 nm to 100 nm, such as from 20 nm to 60 nm, although lesser and greater thicknesses may also be used. The thickness of the second cover dielectric layer 74L may be in a range from 10 nm to 100 nm, such as from 20 nm to 60 nm, although lesser and greater thicknesses may also be used.

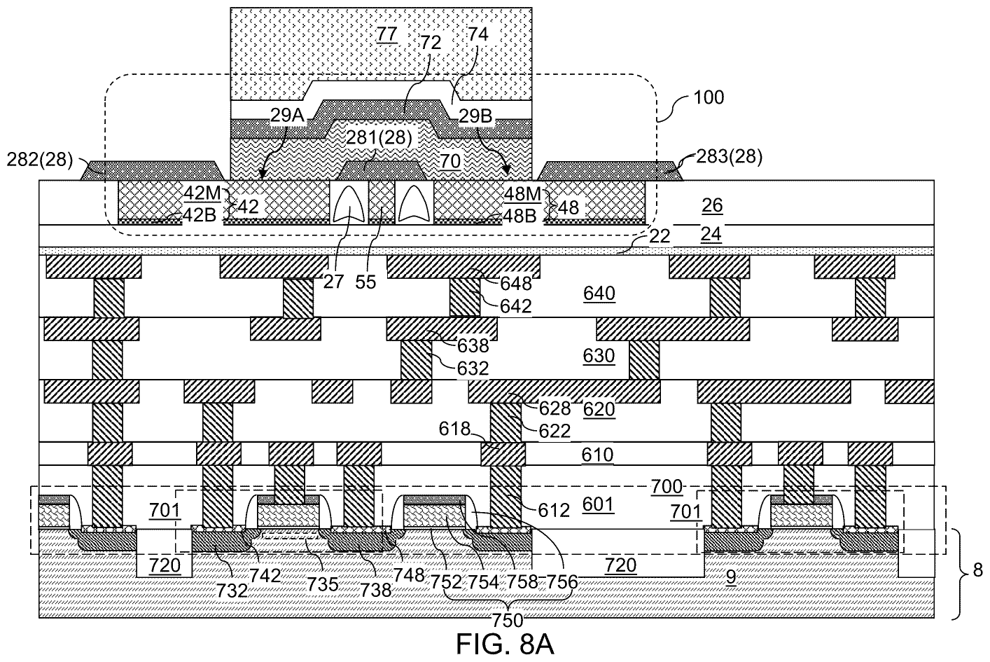

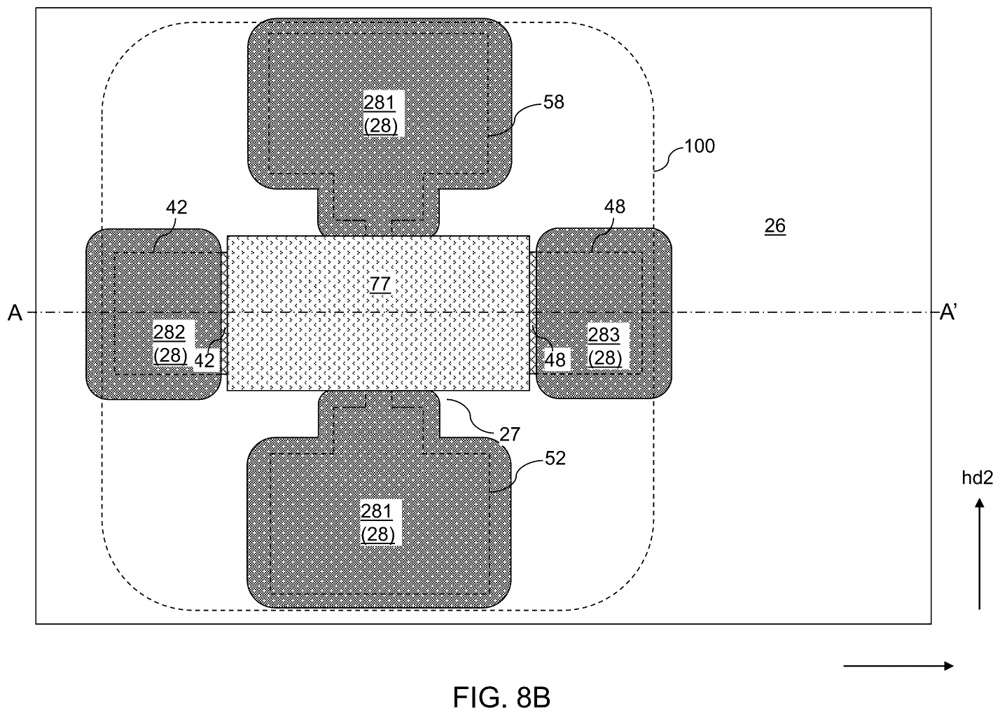

Referring to FIGS. 8A and 8B, a patterned etch mask portion 77 may be formed over the at least one cover dielectric layer (72L, 74L). For example, a photoresist layer may be applied over the at least one cover dielectric layer (72L, 74L), and may be lithographically patterned to provide an elongated photoresist material portion that functions as the patterned etch mask portion 77. The patterned etch mask portion 77 straddles the strip portion 55 of the heater element (52, 55, 58) along the first horizontal direction hd1 and covers portions of the first gap 29A and portions of the second gap 29B that are proximal to the strip portion 55. In one embodiment, the patterned etch mask portion 77 may have a rectangular horizontal cross-sectional shape having lengthwise edges that are parallel to the first horizontal direction hd1 and having widthwise edges that are parallel to the second horizontal direction hd2.

Unmasked portions of at least one cover dielectric layer (72L, 74L) and the phase change material layer 70L may be etched by performing an anisotropic etch process that uses the patterned etch mask portion 77 as an etch mask. Thus, the anisotropic etch process etches portions of the at least one cover dielectric layer (72L, 74L) and the phase change material layer 70L that are not masked by the patterned etch mask portion 77. A remaining portion of the at least one cover dielectric layer (72L, 74L) comprises at least one cover dielectric plate (72, 74). In one embodiment, the at least one cover dielectric plate (72, 74) may comprise a stack of a first cover dielectric plate 72 and a second cover dielectric plate 74. The first cover dielectric plate 72 may comprise a patterned portion of the first cover dielectric layer 72L, and the second cover dielectric plate 74 may comprise a patterned portion of the second cover dielectric layer 74L.

A remaining portion of the phase change material layer 70L comprises a phase change material portion 70, which may also be referred to as a PCM portion 70. The at least one cover dielectric plate (72, 74) and the phase change material portion 70 straddle the strip portion 55 of the heater element (52, 55, 58). The phase change material portion 70 contacts, and extends over, portions of the first electrode 42 and the second electrode 48 that are proximal to the strip portion 55 of the heater element (52, 55, 58). The patterned etch mask portion 77 may be subsequently removed, for example, by ashing.

The phase change material portion 70 covers, and directly contacts, a first portion of the top surface of the first electrode 42 and a first portion of the top surface of the second electrode 48. The phase change material portion 70 is spaced from the strip portion 55 of the heater element (52, 55, 58) by the first dielectric capping plate 281. A second portion of the top surface of the first electrode 42 and a second portion of the top surface of the second electrode 48 may not be covered by the phase change material portion 70 after formation of the phase change material portion 70. In one embodiment, all sidewalls of the at least one cover dielectric plate (72, 74) may be vertically coincident with sidewalls of the phase change material portion 70.

The phase change material portion 70 contacts the first electrode 42 and the second electrode 48, and is spaced from the heater element (52, 55, 58). The phase change material portion 70 is formed on a first surface portion of the first electrode 42 within the first gap 29A and on a first surface portion of the second electrode 48 within the second gap 29B. In other words, the first portion of the top surface of the first electrode 42 within an area of the first gap 29A is contacted by the phase change material portion 70 upon formation of the phase change material portion 70, and the first surface portion of the top surface of the second electrode 48 within an area of the second gap 29B is contacted by the phase change material portion 70 upon formation of the phase change material portion 70.

The combination of the heater element (52, 55, 58), the first electrode 42, the second electrode 48, the dielectric capping plates 28, and the phase change material portion 70 constitutes a phase change material (PCM) switch 100. The PCM switch 100 may be used as a radio-frequency (RF) signal switch. In this embodiment, one of the first electrode 42 and the second electrode 48 may be used as an input node of an RF signal, and another of the first electrode 42 and the second electrode 48 may be used as an output node of the RF signal. The phase change material portion 70 functions as a component that provides a variable resistance between the first electrode 42 and the second electrode 48. Specifically, the phase change material portion 70 may provide an insulating state while the portion of the phase change material that overlies the strip portion 55 of the heater element (52, 55, 58) is in an amorphous phase, and may provide a conducting state while the portion of the phase change material that overlies the strip portion 55 of the heater element (52, 55, 58) is in a polycrystalline phase. Generally, portions of the phase change material portion 70 that are not proximal to the strip portion 55 of the heater element (52, 55, 58) remain polycrystalline, and thus, maintain a conducting state throughout operation of the PCM switch 100.

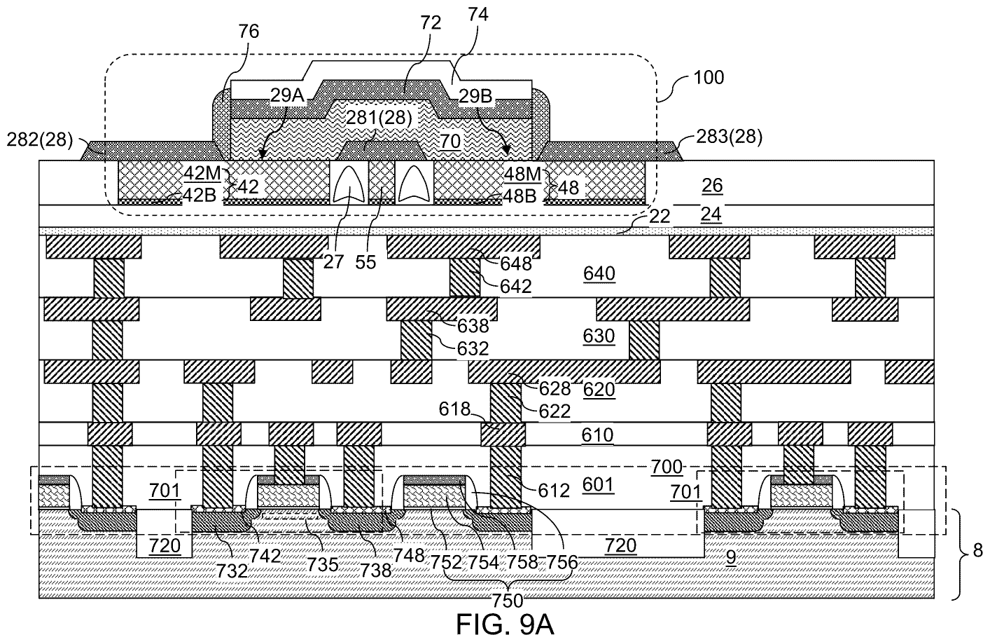

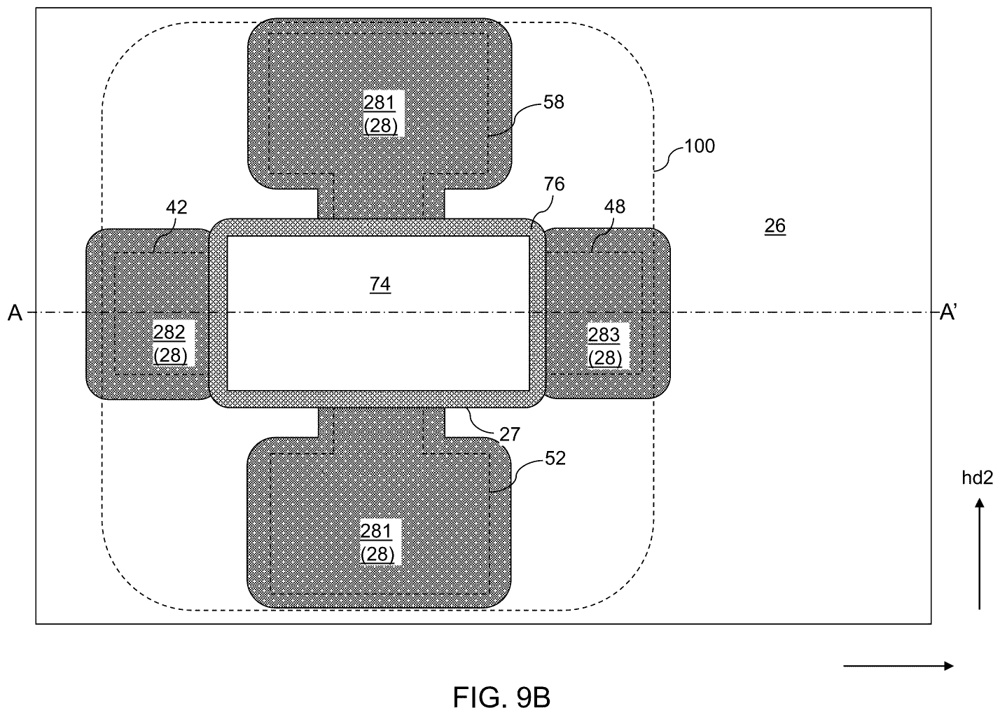

Referring to FIGS. 9A and 9B, a diffusion-barrier dielectric spacer 76 may be formed around the stack of the phase change material portion 70 and the at least one cover dielectric plate (72, 74). Specifically, a diffusion-barrier dielectric layer may be deposited over the at least one cover dielectric plate (72, 74), the phase change material portion 70, the first electrode 42, and the second electrode 48, and an anisotropic etch process (such as a reactive ion etch process) may be performed to remove horizontally-extending portions of the diffusion-barrier dielectric layer. A remaining vertically-extending portion of the diffusion-barrier dielectric layer that laterally surrounds the stack of the phase change material portion 70 and the at least one cover dielectric plate (72, 74) constitutes a diffusion-barrier dielectric spacer 76.

The diffusion-barrier dielectric spacer 76 comprises a dielectric diffusion barrier material such as silicon nitride or silicon carbonitride. The lateral thickness of the diffusion-barrier dielectric spacer 76 may be in a range from 6 nm to 60 nm, such as from 12 nm to 30 nm, although lesser and greater lateral thicknesses may also be used. Generally, the diffusion-barrier dielectric spacer 76 may be formed around the phase change material portion 70 on a second surface portion of the first electrode 42 within the first gap 29A and on a second surface portion of the second electrode 48 within the second gap 29B. Thus, a second portion of the top surface of the first electrode 42 within the area of the first gap 29A is contacted by the diffusion-barrier dielectric spacer 76 upon formation of the diffusion-barrier dielectric spacer 76; and a second portion of the top surface of the second electrode 48 within the area of the second gap 29B is contacted by the diffusion-barrier dielectric spacer 76 upon formation of the diffusion-barrier dielectric spacer 76. A third portion of the top surface of the first electrode 42 within the area of the first gap 29A is exposed upon formation of the diffusion-barrier dielectric spacer 76; and a third portion of the top surface of the second electrode 48 within the area of the second gap 29B is exposed upon formation of the diffusion-barrier dielectric spacer 76.

Thus, the phase change material portion 70 may be encapsulated by the at least one cover dielectric plate (72, 74), the dielectric capping plates 28, the first electrode 42, and the second electrode 48. In one embodiment, surface portions of the dielectric material layer 26 that overlie the encapsulated cavities 27 may contact surface portions of the phase change material portion 70. In this embodiment, each surface of the phase change material portion 70 may contact a respective surface portion of the at least one cover dielectric plate (72, 74), the diffusion-barrier dielectric spacer 76, the first dielectric capping plate 281, the first electrode 42, the second electrode 48, or the dielectric material layer 26. Alternatively, the areas of the first gap 29A and the second gap 29B may be selected such that the top surface of the dielectric material layer 26 is not physically exposed within the areas of the first gap 29A and the second gap 29B. In this embodiment, each surface of the phase change material portion 70 may contact a respective surface portion of the at least one cover dielectric plate (72, 74), the diffusion-barrier dielectric spacer 76, the first dielectric capping plate 28, the first electrode 42, or the second electrode 48. The materials of the at least one cover dielectric plate (72, 74), the diffusion-barrier dielectric spacer 76, the dielectric capping plates 28, the first electrode 42, and the second electrode 48 are resistant to degradation of material property from high temperature thermal cycling. In this embodiment, the reliability of the PCM switch 100 may be enhanced due to the durability of the material components that encapsulate the phase change material portion 70.

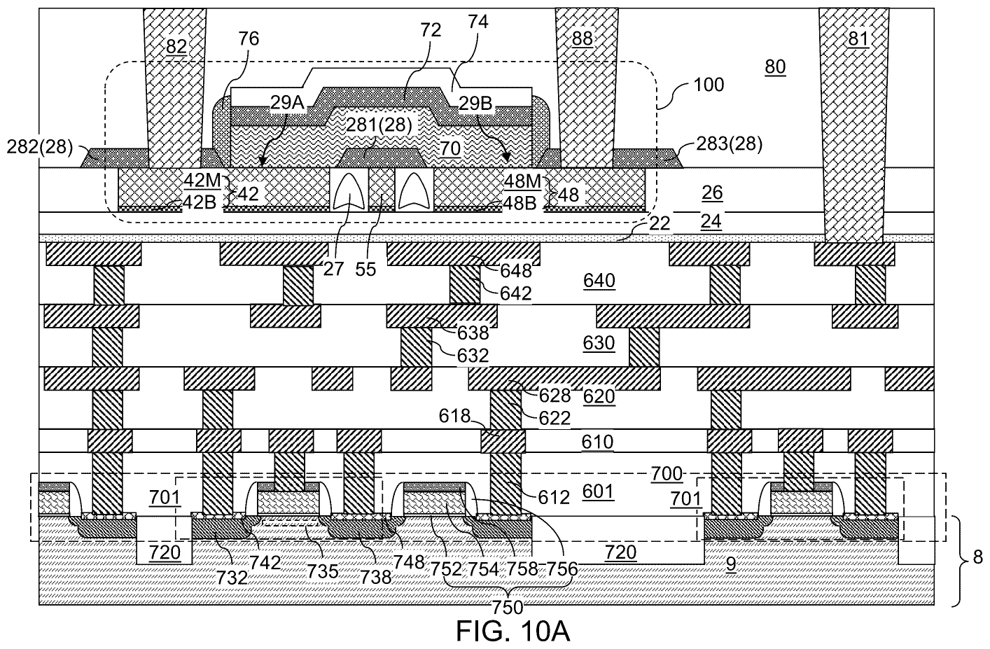

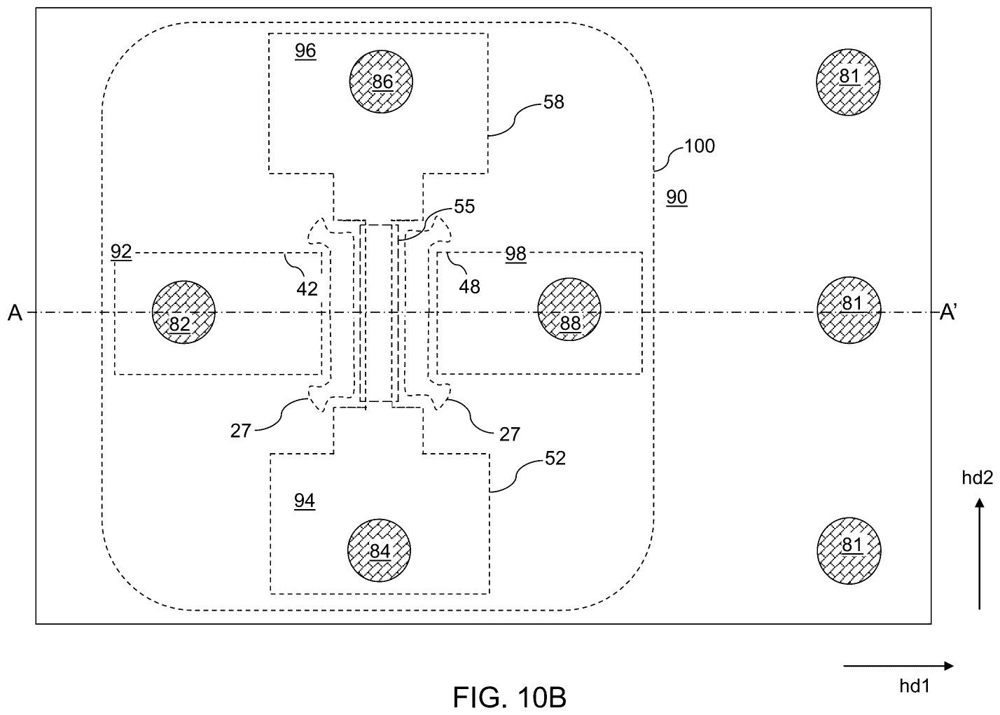

Referring to FIGS. 10A and 10B, a via-level dielectric layer 80 may be subsequently deposited over the at least one cover dielectric plate (72, 74), the diffusion-barrier dielectric spacer 76, and the dielectric capping plates 28. The via-level dielectric layer 80 comprises an interlayer dielectric (ILD) material such as undoped silicate glass, a doped silicate glass, porous or non-porous organosilicate glass, etc. The thickness of the via-level dielectric layer 80 may be in a range from 200 nm to 800 nm, although lesser and greater thicknesses may also be used.

Via cavities may be formed through the via-level dielectric layer 80 over each of the first electrode 42, over the second electrode 48, over a first terminal portion 52 of the heater element (52, 55, 58), over a second terminal portion 58 of the heater element (52, 55, 58), and over metal interconnect structures in underlying interconnect-level dielectric material layers such as fourth metal line structures 648 that are located outside the areas of the PCM switch 100. For example, a photoresist layer may be applied over the via-level dielectric layer 80, and may be lithographically patterned to form discrete openings. Each of the discrete openings may be formed within the area of a respective one of the first electrode 42, the second electrode 48, the first terminal portion 52 of the heater element (52, 55, 58), the second terminal portion 58 of the heater element (52, 55, 58), and over a subset of the underlying metal interconnect structures located outside the area of the PCM switch 100 in a plan view, such as a top-down view.

An anisotropic etch process may be performed to transfer the pattern of the discrete openings in the photoresist layer through the via-level dielectric layer 80, the dielectric capping plates 28, the dielectric material layer 26, the insulating layer 24, and the optional dielectric capping layer 22. Via cavities may be formed through the via-level dielectric layer 80, through the underlying dielectric capping plates 28, and through the dielectric material layer 26, the insulating layer 24, and the optional dielectric capping layer 22 over each of the first electrode 42, the second electrode 48, the first terminal portion 52 of the heater element (52, 55, 58), the second terminal portion 58 of the heater element (52, 55, 58), and the subset of the underlying metal interconnect structures located outside the area of the PCM switch 100. Portions of the top surfaces of the first electrode 42, the second electrode 48, the first terminal portion 52 of the heater element (52, 55, 58), the second terminal portion 58 of the heater element (52, 55, 58), and the subset of the underlying metal interconnect structures located outside the area of the PCM switch 100 may be physically exposed at the bottom of the via cavities. The photoresist layer may be subsequently removed, for example, by ashing.

At least one conductive material, such as a combination of a metallic barrier material and a metallic fill material, may be deposited in the via cavities. The metallic barrier material may comprise one of more of TiN, TaN, WN, and MoN. The metallic fill material may comprise copper or a refractory metal such as tungsten. Excess portions of the at least one conductive material may be removed from above the horizontal plane including the top surface of the via-level dielectric layer 80 by performing a planarization process, which may comprise a chemical mechanical polishing process and/or a recess etch process.

Contact via structures (81, 82, 88, 84, 86) vertically extending through the via-level dielectric layer 80 and through the dielectric capping plates 28 or a combination of the dielectric material layer 26, the insulating layer 24, and the optional dielectric capping layer 22 may be formed in the via cavities. Each of the contact via structures (81, 82, 88, 84, 86) may contact a respective structure that is selected from the first electrode 42, the second electrode 48, the first terminal portion 52 of the heater element (52, 55, 58), and the second terminal portion 58 of the heater element (52, 55, 58). For example, the contact via structures (81, 82, 88, 84, 86) may comprise a first electrode contact via structure 82 that contacts the first electrode 42, a second electrode contact via structure 88 that contacts the second electrode 48, a first heater contact via structure 84 that contacts the first terminal portion 52 of the heater element (52, 55, 58), a second heater contact via structure 86 that contacts a second terminal portion 58 of the heater element (52, 55, 58), and a pad contact via structure 81 that contacts a respective one of the metal interconnect structures underlying the insulating layer 24.

The first electrode contact via structure 82 extends through the via-level dielectric layer 80 and the second dielectric capping plate 282, and contacts a third surface portion of the first electrode 42. The second electrode contact via structure 88 extends through the via-level dielectric layer 80 and the third dielectric capping plate 283, and contacts a third surface portion of the second electrode 48.

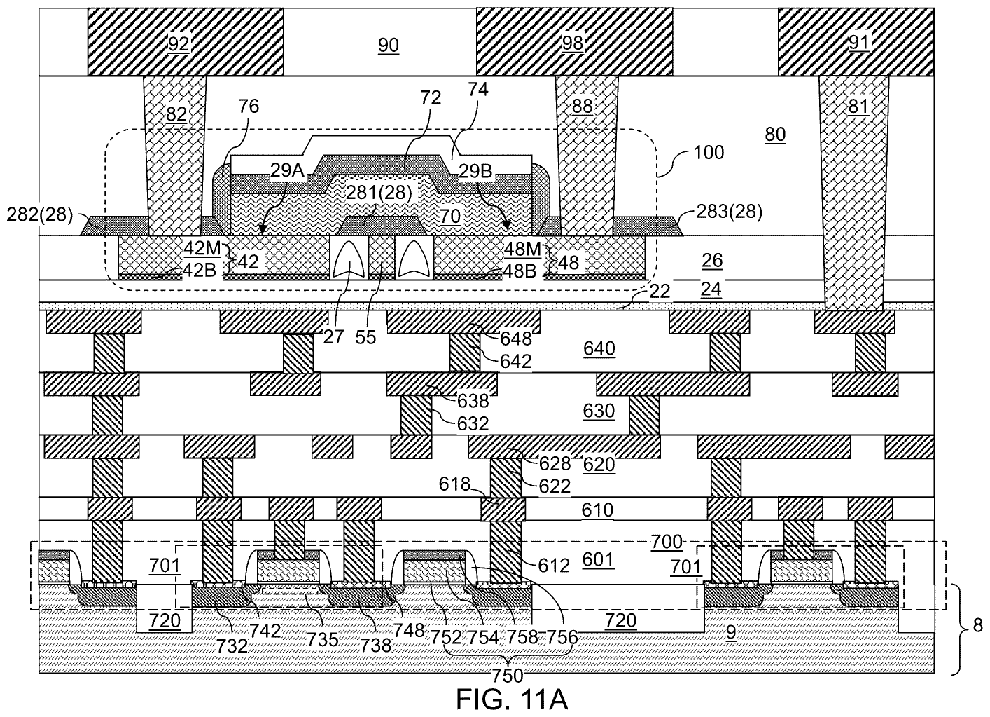

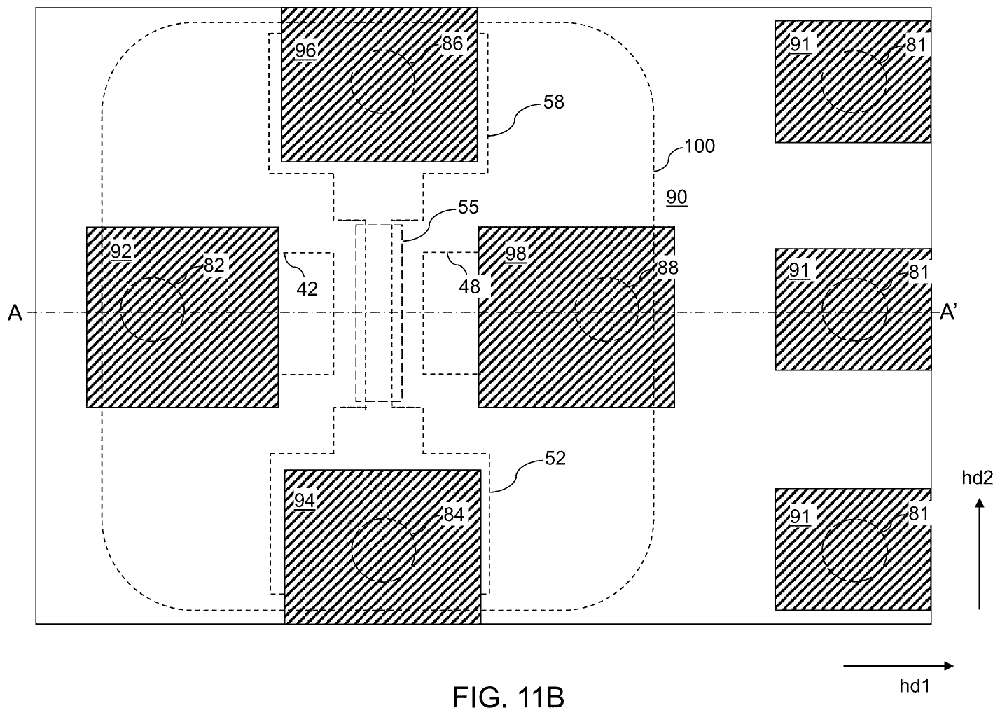

Referring to FIGS. 11A and 11B, a line-level dielectric layer 90 may be formed over the via-level dielectric layer 80. Metal pad/line structures (91, 92, 94, 96, 98) may be formed in the line-level dielectric layer 90 to provide interconnections to the various contact via structures (81, 82, 88, 84, 86). For example, pad/line cavities may be formed through the line-level dielectric layer 90, and at least one metallic material may be deposited in the pad/line cavities. Excess portions of the at least one metallic material may be removed from above the horizontal plane including the top surface of the line-level dielectric layer 90. Remaining portions of the at least one metallic material comprise the metal pad/line structures (91, 92, 94, 96, 98).

The metal/pad line structures (91, 92, 94, 96, 98) may comprise a first electrode-connection metal structure 92 that contacts a top surface of the first electrode contact via structure 82, a second electrode-connection metal structure 98 that contacts a top surface of the second electrode contact via structure 88, a first heater-connection metal structure 94 that contacts a top surface of the first heater contact via structure 84, a second heater-connection metal structure 96 that contacts a top surface of the second heater contact via structure 86, and peripheral connection metal structures 91 each containing a top surface of a respective one of the pad contact via structures 81. Alternatively, a combination of the contact via structures (81, 82, 88, 84, 86) and the metal/pad line structures (91, 92, 94, 96, 98) may be formed as integrated metal interconnect structures including line portions formed within the line-level dielectric layer 90 and via portions formed within the via-level dielectric layer 80.

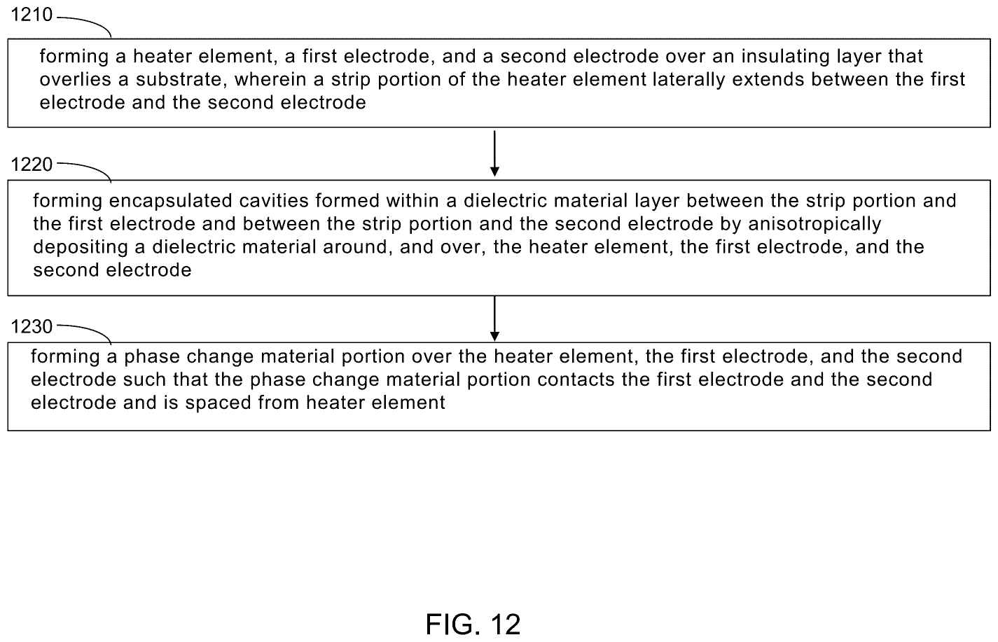

Referring to FIG. 12, a first flowchart illustrates general processing steps for manufacturing a device structure according to embodiments of the present disclosure.

Referring to step 1210 and FIGS. 1A-3B, a heater element (52, 55, 58), a first electrode 42, and a second electrode 48 may be formed over an insulating layer 24 that overlies a substrate 8. A strip portion 55 of the heater element (52, 55, 58) laterally extends between the first electrode 42 and the second electrode 48.

Referring to step 1220 and FIGS. 4-5B, encapsulated cavities 27 formed within a dielectric material layer 26 may be formed between the strip portion 55 and the first electrode 42 and between the strip portion 55 and the second electrode 48 by anisotropically depositing a dielectric material around, and over, the heater element (52, 55, 58), the first electrode 42, and the second electrode 48.

Referring to step 1230 and FIGS. 6A-11B, a phase change material (PCM) portion 70 may be formed over the heater element (52, 55, 58), the first electrode 42, and the second electrode 48 such that the phase change material portion 70 contacts the first electrode 42 and the second electrode 48 and is spaced from the heater element (52, 55, 58).

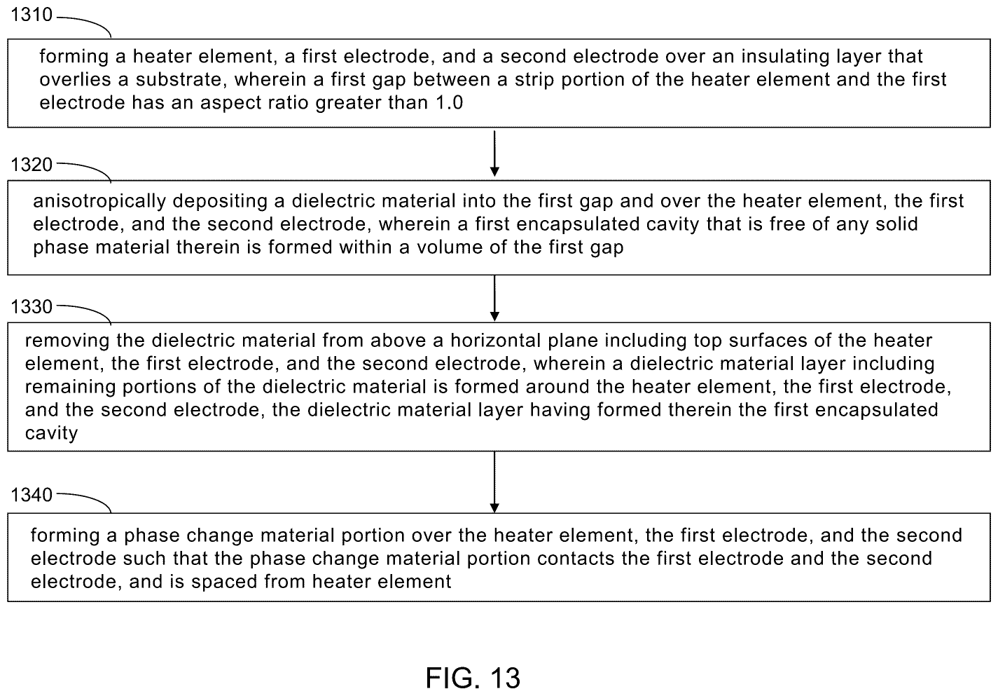

Referring to FIG. 13, a second flowchart illustrates general processing steps for manufacturing a device structure according to embodiments of the present disclosure.

Referring to step 1310 and FIGS. 1A-3B, a heater element (52, 55, 58), a first electrode 42, and a second electrode 48 may be formed over an insulating layer 24 that overlies a substrate 8. A first gap between a strip portion 55 of the heater element (52, 55, 58) and the first electrode 42 has an aspect ratio greater than 1.0.

Referring to step 1320 and FIG. 4, a dielectric material may be deposited into the first gap and over the heater element (52, 55, 58), the first electrode 42, and the second electrode 48. A first encapsulated cavity 27 that is free of any solid phase material therein is formed within a volume of the first gap.

Referring to step 1330 and FIGS. 5A and 5B, the dielectric material may be removed from above a horizontal plane including top surfaces of the heater element (52, 55, 58), the first electrode 42, and the second electrode 48. A dielectric material layer 26 including remaining portions of the dielectric material is formed around the heater element (52, 55, 58), the first electrode 42, and the second electrode 48, the dielectric material layer 26 having formed therein the first encapsulated cavity 27.

Referring to step 1340 and FIGS. 6A-11B, a phase change material (PCM) portion 70 may be formed over the heater element (52, 55, 58), the first electrode 42, and the second electrode 48 such that the phase change material portion 70 contacts the first electrode 42 and the second electrode 48, and is spaced from the heater element (52, 55, 58).

Referring to all drawings and according to various embodiments of the present disclosure, a device structure is provided, which comprises: a heater element (52, 55, 58), a first electrode 42, and a second electrode 48 overlying an insulating layer 24; a dielectric material layer 26 laterally surrounding the heater element (52, 55, 58), the first electrode 42, and the second electrode 48, wherein the dielectric material layer 26 having formed therein a first encapsulated cavity 27 between a strip portion 55 of the heater element (52, 55, 58) and the first electrode 42, and a second encapsulated cavity 27 between the strip portion 55 and the second electrode 48; and a phase change material (PCM) portion 70 extending over a strip portion 55 of the heater element (52, 55, 58) and contacting a first surface portion of the first electrode 42 and a first surface portion of the second electrode 48.

In one embodiment, the device structure comprises dielectric capping plates 28 overlying the dielectric material layer 26 and comprising a first gap 29A overlying the first electrode 42 and a second gap 29B overlying the second electrode 48. The first surface portion of the first electrode 42 is located within an area of the first gap 29A and the first surface portion of the second electrode 48 is located within an area of the second gap 29B. In one embodiment, a top surface of the dielectric material layer 26 is located within a horizontal plane including top surfaces of the heater element (52, 55, 58), the first electrode 42, and the second electrode 48.

In one embodiment, the device structure comprises a diffusion-barrier dielectric spacer 76 laterally surrounding the phase change material portion 70 and contacting a second surface portion of the first electrode 42 and a second surface portion of the second electrode 48. In one embodiment, the device structure comprises: a via-level dielectric layer 80 overlying the phase change material portion 70, the first electrode 42, and the second electrode 48; a first electrode contact via structure 82 contacting a third surface portion of the first electrode 42; and a second electrode contact via structure 88 contacting a third surface portion of the second electrode 48.

In one embodiment, the first electrode contact via structure 82 contacts a first sidewall of the diffusion-barrier dielectric spacer 76; and the second electrode contact via structure 88 contacts a second sidewall of the diffusion-barrier dielectric spacer 76. In one embodiment, the device structure comprises at least one cover dielectric plate (72, 74) overlying the phase change material portion 70 and having sidewalls that are vertically coincident with sidewalls of the phase change material portion 70 and contacting inner sidewalls of the diffusion-barrier dielectric spacer 76.

Embodiments of the present disclosure provide considerable advantages over prior art devices by providing a higher figure of merit for PCM switches, thereby enhancing radio-frequency performance of the PCM switches. The integration of air gaps reduces the dielectric constant around the heater element, and thus, lowers the off-state capacitance without compromising the on-state resistance or the device integrity. Embodiments of the present disclosure provide a cost-effective and reliable solution for PCM switches, and facilitates the integration of PCM switches into semiconductor devices at a low manufacture cost.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a device structure, comprising:
forming a heater element, a first electrode, and a second electrode over an insulating layer that overlies a substrate, wherein a strip portion of the heater element laterally extends between the first electrode and the second electrode;
forming encapsulated cavities within a dielectric material layer between the strip portion and the first electrode and between the strip portion and the second electrode by depositing a dielectric material around, and over, the heater element, the first electrode, and the second electrode; and
forming a phase change material portion over the heater element, the first electrode, and the second electrode such that the phase change material portion contacts the first electrode and the second electrode and is spaced from the heater element.

2. The method of claim 1, further comprising planarizing the dielectric material using top surfaces of the heater element, the first electrode, and the second electrode as stopping surfaces, whereby a top surface of the dielectric material layer is formed within a horizontal plane including the top surfaces of the heater element, the first electrode, and the second electrode.

3. The method of claim 1, further comprising forming dielectric capping plates over the dielectric material layer, wherein the dielectric capping plates comprise:
a first dielectric capping plate that covers the heater element;
a second dielectric capping plate that covers a distal portion of a top surface the first electrode; and
a third dielectric capping plate that covers a distal portion of a top surface of the second electrode.

4. The method of claim 3, wherein:
an entirety of a top surface of the strip portion is contacted by the first dielectric capping plate;
a proximal portion of the first electrode is exposed underneath a first gap between the first dielectric capping plate and the second dielectric capping plate; and
a proximal portion of the second electrode is exposed underneath a second gap between the first dielectric capping plate and the third dielectric capping plate.

5. The method of claim 3, wherein the phase change material portion is formed by:
depositing a phase change material layer over the dielectric capping plates and on the first electrode and the second electrode; and
patterning the phase change material layer by masking a portion of the phase change material layer and by removing an unmasked portion of the phase change material layer, wherein a remaining portion of the phase change material layer comprises the phase change material portion.

6. The method of claim 5, further comprising:
conformally depositing a diffusion-barrier dielectric layer over the phase change material portion, the first electrode, and the second electrode; and
etching the diffusion-barrier dielectric layer by performing an etch process, wherein a remaining vertically-extending portion of the diffusion-barrier dielectric layer comprises a diffusion-barrier dielectric spacer that laterally surrounds the phase change material portion.

7. The method of claim 6, wherein:
a first portion of the top surface of the first electrode is contacted by the phase change material portion upon formation of the phase change material portion; and
a second portion of the top surface of the first electrode is contacted by the diffusion-barrier dielectric spacer upon formation of the diffusion-barrier dielectric spacer.

8. The method of claim 7, further comprising:
forming a via-level dielectric layer over the phase change material portion, the first electrode, and the second electrode; and
forming contact via structures through the via-level dielectric layer, wherein the contact via structures comprise a first electrode-contact via structure that contacts the third portion of the top surface of the first electrode.

9. The method of claim 6, further comprising:
depositing at least one cover dielectric layer over the phase change material layer; and
forming a patterned etch mask portion over the strip portion and over proximal portions of the first electrode and the second electrode, wherein:
the etch process etches portions of the at least one cover dielectric layer and the phase change material layer that are not masked by the patterned etch mask portion; and
remaining portions of the at least one cover dielectric layer comprise at least one cover dielectric plate.

10. A method of forming a device structure, comprising:
forming a heater element, a first electrode, and a second electrode over an insulating layer that overlies a substrate, wherein a first gap between a strip portion of the heater element and the first electrode has an aspect ratio greater than 1.0;
depositing a dielectric material into the first gap and over the heater element, the first electrode, and the second electrode, wherein a first encapsulated cavity that is free of any solid phase material therein is formed within a volume of the first gap;
removing the dielectric material from above a horizontal plane including top surfaces of the heater element, the first electrode, and the second electrode, wherein a dielectric material layer including remaining portions of the dielectric material is formed around the heater element, the first electrode, and the second electrode, the dielectric material layer having formed therein the first encapsulated cavity; and
forming a phase change material (PCM) portion over the heater element, the first electrode, and the second electrode such that the phase change material portion contacts the first electrode and the second electrode, and is spaced from the heater element.

11. The method of claim 10, further comprising forming dielectric capping plates over the dielectric material layer, wherein the phase change material portion is formed on a first surface portion of the first electrode within a first gap among the dielectric capping plates and on a first surface portion of the second electrode within a second gap among the dielectric capping plates.

12. The method of claim 11, further comprising forming a diffusion-barrier dielectric spacer around the phase change material portion on a second surface portion of the first electrode and on a second surface portion of the second electrode.

13. The method of claim 10, further comprising:
forming a via-level dielectric layer over the phase change material portion, the diffusion-barrier dielectric spacer, the first electrode, and the second electrode;
forming a first electrode-contact via structure through the via-level dielectric layer on a third surface portion of the first electrode.

14. A device structure comprising:
a heater element, a first electrode, and a second electrode overlying an insulating layer;
a dielectric material layer laterally surrounding the heater element, the first electrode, and the second electrode, wherein the dielectric material layer having formed therein a first encapsulated cavity between a strip portion of the heater element and the first electrode, and a second encapsulated cavity between the strip portion and the second electrode; and
a phase change material (PCM) portion extending over a strip portion of the heater element and contacting a first surface portion of the first electrode and a first surface portion of the second electrode.

15. The device structure of claim 14, further comprising dielectric capping plates overlying the dielectric material layer, wherein the first surface portion of the first electrode is located within an area of a first gap among the dielectric capping plates and the first surface portion of the second electrode is located within an area of a second gap among the dielectric capping plates.

16. The device structure of claim 15, wherein a top surface of the dielectric material layer is located within a horizontal plane including top surfaces of the heater element, the first electrode, and the second electrode.

17. The device structure of claim 14, further comprising a diffusion-barrier dielectric spacer laterally surrounding the phase change material portion and contacting a second surface portion of the first electrode and a second surface portion of the second electrode.

18. The device structure of claim 17, further comprising:
a via-level dielectric layer overlying the phase change material portion, the first electrode, and the second electrode; and
a first electrode-contact via structure contacting a third surface portion of the first electrode.

19. The device structure of claim 17, further comprising at least one cover dielectric plate overlying the phase change material portion and having sidewalls that are vertically coincident with sidewalls of the phase change material portion and contacting inner sidewalls of the diffusion-barrier dielectric spacer.

20. The device structure of claim 14, wherein top surfaces of the heater element, the first electrode, and the second electrode are located within a horizontal plane including a top surface of the dielectric material layer.
